(19) United States
(12) Patent Application Publication
(10) Pub. No.: US 2012/0103411 A1
(43) Pub. Date: May 3, 2012

(54) PHOTOVOLTAIC MODULE SUBSTRATE

(76) Inventor: Pedro Gonzalez, Fremont, CA (US)

(21) Appl. No.: 13/284,411

(22) Filed: Oct. 28, 2011

Related U.S. Application Data
(60) Provisional application No. 61/408,394, filed on Oct. 29, 2010.

(51) Int. Cl. H01L 31/0264; H01L 31/18; H01L 31/0224

(52) U.S. Cl. 136/256; 136/252; 136/262; 438/95; 257/E31.126

(57) ABSTRACT

A photovoltaic module may include a back glass including a cobalt oxide or copper oxide.

### TECHNICAL FIELD

The present invention relates to photovoltaic modules and methods of manufacturing same.

### BACKGROUND

Photovoltaic modules can include semiconductor material deposited over a substrate, for example, with a first layer serving as a window layer and a second layer serving as an absorber layer. The semiconductor window layer can allow the penetration of solar radiation to the absorber layer, which converts solar energy to electricity. Existing photovoltaic modules suffer from various performance issues due to poor thermal budget.

### DESCRIPTION OF DRAWINGS

FIG. 1 is a schematic of a photovoltaic module having multiple layers.

FIG. 2 is a schematic of a photovoltaic module having multiple layers.

FIG. 3 is a schematic of a multilayered structure.

FIG. 4 is a schematic of a photovoltaic module having multiple layers.

FIG. 5 is a schematic of a system for generating electricity.

### DETAILED DESCRIPTION

Photovoltaic modules can include multiple layers created on a substrate (or superstrate). For example, a photovoltaic module can include a barrier layer, a transparent conductive oxide (TCO) layer, a buffer layer, and a semiconductor layer (or active layer) formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the module and/or all or a portion of the layer or substrate underlying the layer. For example, a “layer” can include any amount of any material that contacts all or a portion of a surface.

Photovoltaic modules can be formed on optically transparent substrates, such as glass. Because glass is not conductive, a front contact, which may include a multilayered stack consisting of a transparent conductive oxide layer, is typically deposited between the substrate and the semiconductor bi-layer. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a-reduced number of pin holes and having high sodium-blocking capability, and good adhesive properties.

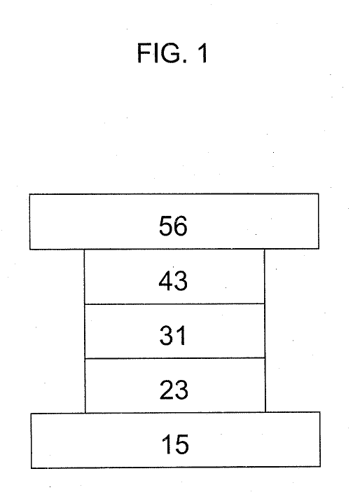

Referring to FIG. 1, by way of example, a photovoltaic module may include a first substrate 15 with a front contact 23 formed adjacent thereto. A semiconductor layer 31 may be positioned adjacent to front contact 23, which may be part of a TCO stack. A back contact may be positioned adjacent to semiconductor layer 31, and a back support 56 may be applied adjacent thereto. It should be noted and appreciated that any of the aforementioned layers may include multiple layers, and that adjacent does not mean “directly on,” such that in some embodiments, one or more additional layers may be positioned between the layers depicted. For example, a barrier layer may be positioned between first substrate 15 and transparent conductive oxide layer 23, and a buffer layer may be positioned between transparent conductive oxide layer 23 and semiconductor layer 31. First substrate 15 and back support 56 may serve as front and back supports for the photovoltaic module, and may both include glass, e.g., soda-lime glass. The composition of the glass for both supports may have a substantial impact on the thermal budget of the photovoltaic module. Thermal budget in this context refers to the temperature exposure (both temperature range and duration of exposure) that a photovoltaic module can withstand before performance begins to suffer.

The thermal budget of a photovoltaic module is thus important both from a performance/yield perspective and a reliability standpoint of view. The performance of photovoltaic modules improves as temperature decreases. For example, for a cadmium telluride device, the performance decreases at the rate of about 0.3%/degrees C.; for silicon devices, the performance loss is a bit worse at about 0.5%/degrees C.; and for CIGS (cadmium-indium-gallium-selenium) devices, the performance loss is about 0.6%/degrees C. The reliability of the module is also affected by the high temperatures. For example, polymeric materials on the module degrade following an Arrhenius relation, and the water permeation rate also has an exponential relation with temperature.

One method of improving the thermal budget of a photovoltaic module is to incorporate an electrically isolating, thermally conductive material into the module. Various suitable materials may be used, including, for example, a copper/cobalt oxide-containing glass, or a ceramic material, such as alumina. The electrically isolating, thermally conductive material may occupy any suitable space in the module and may serve any of a variety of functions, including, for example, as a front or back support for the module. For example, a photovoltaic module with an improved thermal budget may include a back glass including a high copper oxide or cobalt oxide content (e.g., about 10 to about 25 weight percent). Typically, soda-lime glass has a thermal conductivity of about 1.1 W/k m. Copper oxide or cobalt oxide glass has a thermal conductivity of about 2 to about 3 times higher. Thus use of a glass containing a high copper/cobalt oxide content can result in a net improvement in thermal conductivity of more than about 1 W/k m, more than about 2 W/K m, or more than about 3 W/K m. The change in temperature is proportional to the glass thickness and inversely proportional to the thermal conductivity. Thus by raising the thermal conductivity of the glass, the temperature experienced by the module can be decreased. It should be noted and appreciated that although many of the embodiments disclosed herein discuss use of the electrically isolating, thermally conductive material as a back support, that it may also be suitable for use as a front support. The improved thermal budget of a photovoltaic module fabricated therefrom may compensate for any efficiency lost as a result of the red/blue tint commonly associated with copper/cobalt oxide glass.

In one aspect, a multilayered structure may include a back glass comprising a cobalt oxide or a copper oxide. The multilayered structure may include a contact layer adjacent to the back glass.

The back glass may include a cobalt oxide content of more than about 5 wt. %. The back glass may include a copper oxide content of more than about 5 wt. %. The back glass may include a copper oxide content of less than about 30 wt. %. The back glass may include a cobalt oxide content of less than about 30 wt. %. The back glass may include a thermal conductivity of more than about 1 W/K m. The back glass may include a thermal conductivity of less than about 3 W/K m. The multilayered structure may include a cadmium telluride layer adjacent to the contact layer, and a cadmium sulfide layer adjacent to the cadmium telluride layer. The contact layer may include molybdenum, nickel, copper, aluminum, titanium, palladium, or chrome. The multilayered structure may include a copper-indium-gallium-diselenide layer adjacent to the contact layer. The contact layer may include a chromium or molybdenum.

In one aspect, a photovoltaic module may include a glass substrate comprising a cobalt oxide or a copper oxide. The photovoltaic module may include a contact layer adjacent to the glass substrate. The photovoltaic module may include a copper-indium-gallium-diselenide layer (CIGS) adjacent to the contact layer.

The glass substrate may include a cobalt oxide content of about 5 to about 30 wt. %. The glass substrate may include a copper oxide content of about 5 to about 30 wt. %. The glass substrate may include a thermal conductivity of about 1 to about 3 W/K m. The photovoltaic module may include a transparent conductive oxide layer adjacent to the CIGS layer. The photovoltaic module may include a cadmium sulfide buffer layer between the copper-indium-gallium-diselenide layer and the transparent conductive oxide layer. The photovoltaic module may include a zinc-containing layer between the cadmium sulfide buffer layer and the transparent conductive oxide layer.

In one aspect, a photovoltaic module may include a glass substrate. The photovoltaic module may include a transparent conductive oxide layer adjacent to the glass substrate. The photovoltaic module may include a cadmium sulfide layer adjacent to the transparent conductive oxide layer. The photovoltaic module may include a cadmium telluride layer adjacent to the cadmium sulfide layer. The photovoltaic module may include a back contact layer adjacent to the cadmium telluride layer. The photovoltaic module may include a back cover glass including a cobalt oxide or a copper oxide adjacent to the back contact layer.

In one aspect, a method of manufacturing a photovoltaic module may include depositing a contact layer adjacent to a substrate. The substrate may include a cobalt oxide or a copper oxide. The method may include depositing a copper-indium-gallium-diselenide layer adjacent to the contact layer.

The method may include depositing a cadmium sulfide buffer layer adjacent to the copper-indium-gallium-diselenide layer. The method may include depositing a transparent conductive oxide layer adjacent to the cadmium sulfide buffer layer. The method may include depositing a zinc-containing layer adjacent to the cadmium sulfide buffer layer and the transparent conductive oxide layer.

In one aspect, a method of manufacturing a photovoltaic module may include depositing a transparent conductive oxide layer adjacent to a glass substrate. The method may include depositing a cadmium sulfide layer adjacent to the transparent conductive oxide layer. The method may include depositing a cadmium telluride layer adjacent to the cadmium sulfide layer. The method may include depositing a back contact layer adjacent to the cadmium telluride layer. The method may include applying a back cover glass including a cobalt oxide or a copper oxide adjacent to the back contact layer.

In one aspect, a photovoltaic module may include a back glass including cobalt oxide or copper oxide. The photovoltaic module may include a contact layer adjacent to the back glass. The photovoltaic module may include a semiconductor layer adjacent to the contact layer.

The semiconductor layer may include a cadmium sulfide layer adjacent to a cadmium telluride layer. The semiconductor layer may include a copper-indium-gallium-diselenide layer (CIGS). The semiconductor layer may include amorphous or crystalline silicon.

The copper/cobalt oxide glass may be incorporated into a multilayer structure containing any suitable photovoltaic device material, including, for example, cadmium telluride or CIGS (e.g., copper-indium-gallium-diselenide). In some circumstances, the red/blue tint associated with the copper/cobalt oxide may have certain visual appeal. The copper/cobalt oxide glass may be manufactured manually (i.e., by applying one or more cobalt or copper-containing coatings on a glass), or it may be obtained from a commercial manufacturer. It should be appreciated that various materials in addition to or aside from copper/cobalt oxide glass may be incorporated into a photovoltaic module to improve thermal budget, including, for example, any material having high dielectric properties and which is able to sustain high temperatures and high conductivity. For example, various ceramic materials may be used, including, for example, alumina.

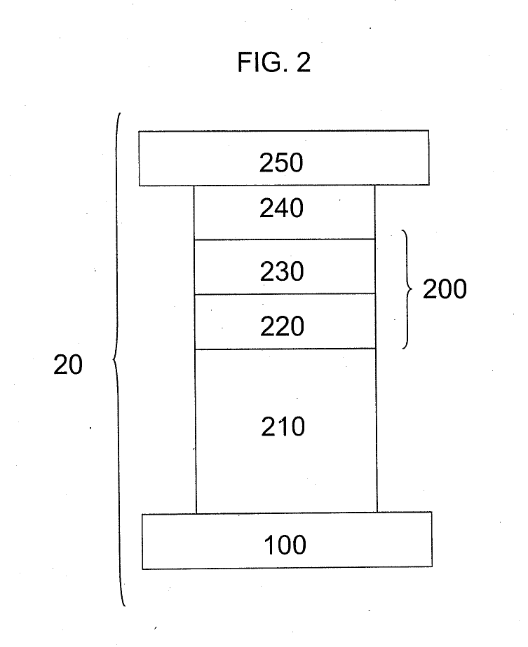

An electrically insulating, thermally conductive material may be incorporated into a cadmium telluride device/module to improve thermal budget. Referring to FIG. 2, by way of example, photovoltaic module 20 may include a back support 250. Back support 250 may include a glass (e.g., a soda-lime glass), and may contain a quantity of copper oxide or cobalt oxide. Back support 250 may contain any suitable quantity of copper/cobalt oxide, including, for example, more than about 5 wt. %, more than about 10 wt. %, more than about 15 wt. %, less than about 30 wt. %, or less than about 25 wt. %. Back support 250 may also contain a reduced sodium oxide, fluorine, or titanium dioxide content. For example, back support 250 may contain less than about 20% sodium oxide, less than about 15% sodium oxide, or less than about 10% sodium oxide. For example, back support 250 may contain about 12% sodium oxide. Back support 250 may contain trace amounts of fluorine or titanium dioxide. For example, back support 250 may contain less than about 2%, less than about 1%, or less than about 0.5% fluorine or titanium dioxide. Back support 250 may have any suitable thickness, including, for example, more than about 1 mm, more than about 3 mm, more than about 5 mm, more than about 8 mm, or less than about 10 mm. The copper/cobalt oxide content of back support 250 can result in an improved thermal budget for any photovoltaic module/device fabricated therefrom.

Glass including cobalt oxide can be manufactured by mixing a quantity of cobalt with molten glass during the glass manufacture process. The cobalt can react with an oxygen ambient to form cobalt oxide in the resulting glass. The amount of cobalt oxide in the final glass product can be controlled by controlling the amount of cobalt mixed with the molten glass. Cobalt glass can be formed as a glass sheet for use as a substrate using any suitable glass production process, such as rolling or floating. The resulting glass can have a blue color. Similarly, glass including copper oxide can be manufactured by mixing a quantity of copper with molten glass during the glass manufacture process. The copper can react with an oxygen ambient to form copper oxide in the resulting glass. The amount of copper oxide in the final glass product can be controlled by controlling the amount of copper mixed with the molten glass. Copper glass can be formed as a glass sheet for use as a substrate using any suitable glass production process, such as rolling or floating. The resulting glass can have a copper or amber color.

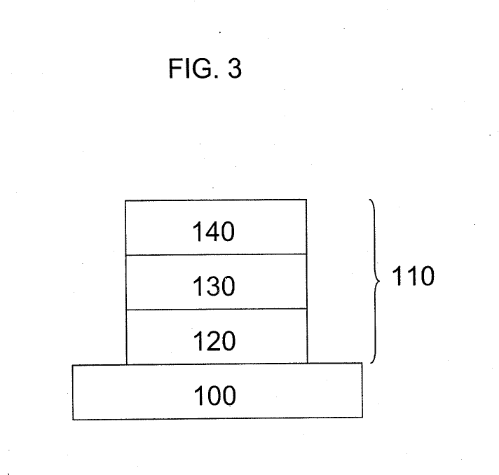

Back support 250 may be placed adjacent to a back contact 240, which may include any suitable material, including, for example, molybdenum, nickel, copper, aluminum, titanium, palladium, or chrome. Back contact 240 may be deposited adjacent to semiconductor bi-layer 200, which may be positioned adjacent to an annealed transparent conductive oxide stack 210. Annealed transparent conductive oxide stack 210 may be deposited onto a substrate 100, which may serve as a front support for photovoltaic module 20. Annealed transparent conductive oxide stack 210 may be fabricated from transparent conductive oxide stack 110 from FIG. 3.

Referring to FIG. 3, a barrier layer 120 may be deposited onto substrate 100. Substrate 100 may include any suitable material, including, for example, a glass. The glass may include a soda-lime glass, or any glass with reduced iron content. Substrate 100 may undergo a treatment step, during which one or more edges of the glass may be substantially rounded. The glass may have any suitable transmittance, including about 450 nm to about 800 nm. The glass may also have any suitable transmission percentage, including, for example, more than about 50%, more than about 60%, more than about 70%, more than about 80%, or more than about 85%. For example, substrate 100 may include a glass with about 90% transmittance.

Barrier layer 120 may be deposited adjacent to substrate 100 using any suitable technique, including, for example, sputtering. Barrier layer 120 may include any suitable material, including, for example, silicon aluminum oxide. Barrier layer 120 can be incorporated between the substrate and the TCO layer to lessen diffusion of sodium or other contaminants from the substrate to the semiconductor layers, which could result in degradation or delamination. Barrier layer 120 can be transparent, thermally stable, with a reduced number of pin holes and having high sodium-blocking capability, and good adhesive properties. Barrier layer 120 can include any suitable number of layers and may have any suitable thickness, including, for example, more than about 500 A, more than about 750 A, or less than about 1200 A. For example, barrier layer 120 may have a thickness of about 1000 A.

A transparent conductive oxide layer 130 can be formed adjacent to barrier layer 120. Transparent conductive oxide layer 130 may be deposited using any suitable means, including, for example, sputtering. Transparent conductive oxide layer 130 may include any suitable material, including, for example, an amorphous layer of cadmium stannate. Transparent conductive oxide layer 130 may have any suitable thickness, including, for example, more than about 2000 A, more than about 2500 A, or less than about 3000 A. For example, transparent conductive oxide layer 130 may have a thickness of about 2600 A.

A buffer layer 140 may be formed onto transparent conductive oxide layer 130. Buffer layer 140 can be deposited between the TCO layer and a semiconductor window layer to decrease the likelihood of irregularities occurring during the formation of the semiconductor window layer. Buffer layer 140 may include any suitable material, including, for example, an amorphous tin oxide, zinc tin oxide, zinc oxide, or zinc magnesium oxide. Buffer layer 140 may be deposited using any suitable means, including, for example, sputtering.

Following deposition, transparent conductive oxide stack 110 can be annealed to form annealed stack 210 from FIG. 2. Transparent conductive oxide stack 110 can be annealed using any suitable annealing process. The annealing can occur in the presence of a gas selected to control an aspect of the annealing, including, for example, nitrogen gas. Transparent conductive oxide stack 110 can be annealed under any suitable pressure, for example, under reduced pressure, in a low vacuum, or at about 0.01 Pa (10⁻⁴ Torr). Transparent conductive oxide stack 110 can be annealed at any suitable temperature or temperature range. For example, transparent conductive oxide stack 110 can be annealed above about 380 degrees C., above about 400 degrees C., above about 500 degrees C., above about 600 degrees C., or below about 800 degrees C. For example, transparent conductive oxide stack 110 can be annealed at about 400 degrees C. to about 800 degrees C. or about 500 degrees C. to about 700 degrees C. Transparent conductive oxide stack 110 can be annealed for any suitable duration. Transparent conductive oxide stack 110 can be annealed for more than about 10 minutes, more than about 20 minutes, more than about 30 minutes, or less than about 40 minutes. For example, transparent conductive oxide stack 110 can be annealed for about 15 to about 20 minutes.

Annealed transparent conductive oxide stack 210 can be used to form photovoltaic module 20 from FIG. 2, which shows semiconductor layer 200 adjacent to transparent conductive oxide stack 210. Semiconductor layer 200 can include a semiconductor window layer 220 and a semiconductor absorber layer 230. Semiconductor window layer 220 can be deposited directly onto annealed transparent conductive oxide stack 210. Semiconductor window layer 220 can be deposited using any known deposition technique, including, for example, vapor transport deposition. Semiconductor absorber layer 230 can be deposited onto semiconductor window layer 220. Semiconductor absorber layer 230 can be deposited using any known deposition technique, including, for example, vapor transport deposition. Semiconductor window layer 220 can include a cadmium sulfide layer. Semiconductor absorber layer 230 can include a cadmium telluride layer. Back contact 240 can be deposited onto semiconductor layer 200. And the copper/cobalt oxide-containing back support 250 can be placed onto back contact 240.

The incorporation of the copper/cobalt oxide glass into photovoltaic module 20 can result in improved module performance due to an improved thermal budget. For example, photovoltaic module 20 can demonstrate a net improvement in thermal conductivity of about 1.1 W/K m to about 2 W/K m or more. The incorporation of copper oxide or cobalt oxide into back support 250 of photovoltaic module 20 can result in a reduced thermal fluctuation of more than about 2 degrees C., more than about 5 degrees C., more than about 10 degrees C., or less than about 20 degrees C. For example, the use of copper/cobalt oxide-containing back support 250 can reduce thermal fluctuation within photovoltaic module 20 by about 5 to about 10 degrees C., thereby improving the performance and reliability of the module.

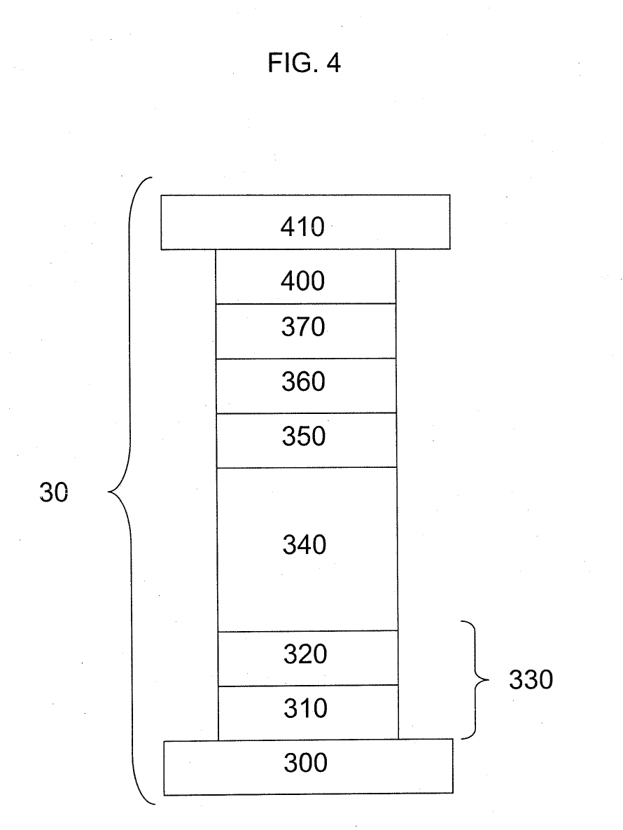

An electrically insulating, thermally conductive material may also be incorporated into a CIGS device/module to improve thermal budget. Referring to FIG. 4, by way of example, a photovoltaic module 30 can include a chromium layer 310 deposited on a back support 300.

Back support 300 may include a glass (e.g., soda-lime glass), or any glass with reduced iron content. Back support 300 may contain a quantity of copper oxide or cobalt oxide, as described above in connection with FIG. 2. Back support 300 may contain any suitable quantity of copper/cobalt oxide, including, for example, more than about 5 wt. %, more than about 10 wt. %, more than about 15 wt. %, less than about 30 wt. %, or less than about 25 wt. %. Back support 300 may also contain a reduced sodium oxide, fluorine, or titanium dioxide content. For example, back support 300 may contain less than about 20% sodium oxide, less than about 15% sodium oxide, or less than about 10% sodium oxide. For example, back support 300 may contain about 12% sodium oxide. Back support 300 may contain trace amounts of fluorine or titanium dioxide. For example, back support 300 may contain less than about 2%, less than about 1%, or less than about 0.5% fluorine or titanium dioxide. Back support 300 may have any suitable thickness, including, for example, more than about 1 mm, more than about 3 mm, more than about 5 mm, more than about 8 mm, or less than about 10 mm. The copper/cobalt oxide content of back support 300 can result in an improved thermal budget for any photovoltaic module/device fabricated therefrom.

Chromium layer 310 can be deposited using any suitable means, including sputtering. A molybdenum can be doped with sodium to form sodium-doped molybdenum layer 320. Sodium-doped molybdenum layer 320 can be deposited onto chromium layer 310 using any suitable means, including sputtering. Sodium-doped molybdenum layer 320 and chromium layer 330 can form back contact metal 330. A copper-indium-gallium-diselenide layer (CIGS) 340 can be deposited onto contact metal 330. CIGS layer 340 may include a copper layer, a gallium layer, an indium layer, and a selenium layer 330. CIGS layer 340 can be formed and deposited using any suitable method. For example, back support 300 and back contact metal 330 can be heated to a deposition temperature above about 200° C. A copper can be evaporated over the substrate layers; a gallium can be sputtered onto the copper; and then an indium and a selenium can be co-evaporated over the gallium. Alternatively, the copper, gallium, indium, and selenium can be co-evaporated over the substrate.

In one variation, the copper, gallium, and indium all go through a selenization process. For example, the copper, gallium, and indium can be deposited and then heated in the presence of a selenium flux. Alternatively, the copper, gallium, and indium can be deposited in the presence of a hydrogen selenide gas. Photovoltaic module 30 can undergo heat treatment during which sodium from sodium-doped molybdenum layer 320 can diffuse into chromium layer 310 to create a concentration gradient. It should be noted that the metal contact layer(s) are not limited to any specific metals. Each layer can include any suitable metal or alloy, including molybdenum, aluminum, chromium, iron, nickel, titanium, vanadium, manganese, cobalt, zinc, ruthenium, tungsten, silver, gold, or platinum. Each layer can also be of a suitable thickness, for example greater than about 10 A, greater than about 20 A, greater than about 50 A, greater than about 100 A, greater than about 250 A, greater than about 500 A, less than about 2000 A, less than about 1500 A, less than about 1000 A, or less than about 750 A. One of the layers can include a suitable dopant material, including copper, antimony, potassium, sodium, cesium, silver, gold, phosphorous, arsenic, or bismuth. Each layer can be substantially pure, containing a single metal or a binary alloy, mixture, or solid solution thereof.

Continuing, a cadmium sulfide buffer layer 350 can be deposited adjacent to CIGS layer 340. Cadmium sulfide buffer layer 350 can have a thickness of about 500 A. Cadmium sulfide buffer layer 350 can be deposited using any known deposition technique, including vapor transport. A layer of intrinsic zinc oxide 360 can be deposited onto buffer layer 350. Intrinsic zinc oxide layer 360 can have a thickness of about 600 A. Intrinsic zinc oxide layer 360 can be deposited using any suitable method, including sputtering. Intrinsic zinc oxide layer 360 can also be deposited in the presence of a gas, for example argon gas, oxygen gas, or a combination thereof. A doped zinc oxide 370 can be deposited onto intrinsic zinc oxide 360. Doped zinc oxide 370 can have a thickness of about 5000 A. Doped zinc oxide 370 can be deposited using any suitable deposition method, including sputtering. Doped zinc oxide 370 can be deposited in the presence of a gas, for example argon gas.

Photovoltaic module 30 can include a transparent conductive oxide layer 400 deposited adjacent to doped zinc oxide 370 to serve as a front contact. Transparent conductive oxide layer 400 can include any suitable material, for example cadmium stannate. One or more additional layer(s) can be deposited adjacent to transparent conductive oxide layer 400, including for example one or more barrier layers to block the diffusion of unwanted chemicals. The one or more barrier layers can include any suitable material, including a silicon nitride, silicon oxide, aluminum-doped silicon oxide, boron-doped silicon nitride, phosphorus-doped silicon nitride, silicon oxide-nitride, or any combination or alloy thereof. A front support 410 may be applied adjacent to transparent conductive oxide layer. Front support 410 may include a glass (e.g., soda-lime glass).

The incorporation of the copper/cobalt oxide glass into photovoltaic module 30 can result in improved module performance due to an improved thermal budget. For example, photovoltaic module 30 can demonstrate a net improvement in thermal conductivity of about 1.1 W/K m to about 2 W/K m or more. The incorporation of copper oxide or cobalt oxide into back support 300 of photovoltaic module 30 can result in a reduced thermal fluctuation of more than about 2 degrees C., more than about 5 degrees C., more than about 10 degrees C., or less than about 20 degrees C. For example, the use of copper/cobalt oxide-containing back support 300 can reduce thermal fluctuation within photovoltaic module 30 by about 5 to about 10 degrees C., thereby improving the performance and reliability of the module.

Photovoltaic devices/cells fabricated using the methods discussed herein may be incorporated into one or more photovoltaic modules. The modules may be incorporated into various systems for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from one photovoltaic cell may be combined with photocurrent generated from other photovoltaic cells. For example, the photovoltaic cells may be part of one or more photovoltaic modules in a photovoltaic array, from which the aggregate current may be harnessed and distributed.

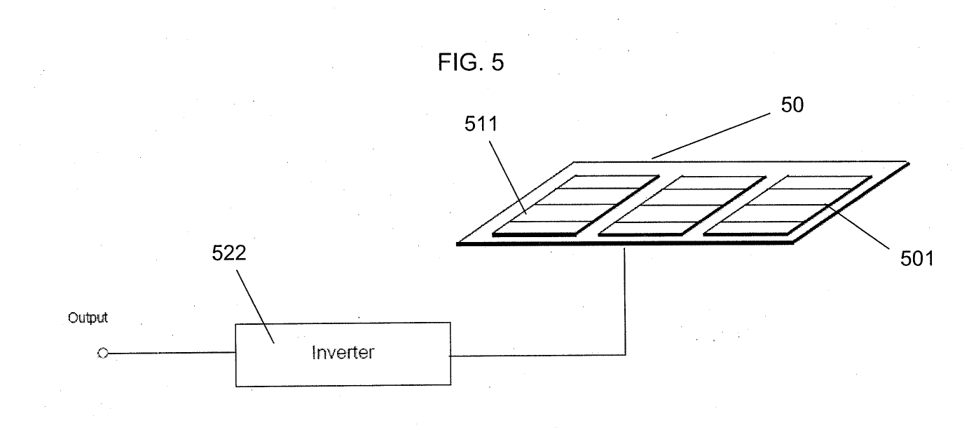

Referring to FIG. 5, by way of example, a photovoltaic array 50 may include one or more interconnected photovoltaic modules 501. One or more of photovoltaic modules 501 may include one or more photovoltaic cells 511 having any of the multilayer structure or photovoltaic device configurations discussed herein. Photovoltaic array 50 may be illuminated with a light source, e.g., the sun, or any suitable artificial light source, to generate a photocurrent. For example, photovoltaic array 50 may be illuminated with a wavelength of light between about 400 nm to about 700 nm. The generated photocurrent may be converted from direct current (DC) to alternating current (AC) using, for example, an inverter 522. The converted current may be output for any of a variety of uses, including, for example, connection to one or more home appliances, or to a utility grid.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A multilayered structure comprising:
a back glass comprising a cobalt oxide or a copper oxide; and
a contact layer adjacent to the back glass.

2. The multilayered structure of claim 1, wherein the back glass comprises a cobalt oxide content of more than about 5 wt. %.

3. The multilayered structure of claim 1, wherein the back glass comprises a copper oxide content of more than about 5 wt. %.

4. The multilayered structure of claim 1, wherein the back glass comprises a copper oxide content of less than about 30 wt. %.

5. The multilayered structure of claim 1, wherein the back glass comprises a cobalt oxide content of less than about 30 wt. %.

6. The multilayered structure of claim 1, wherein the back glass comprises a thermal conductivity of more than about 1 W/K m.

7. The multilayered structure of claim 1, wherein the back glass comprises a thermal conductivity of less than about 3 W/K m.

8. The multilayered structure of claim 1, further comprising a cadmium telluride layer adjacent to the contact layer, and a cadmium sulfide layer adjacent to the cadmium telluride layer.

9. The multilayered structure of claim 8, wherein the contact layer comprises molybdenum, nickel, copper, aluminum, titanium, palladium, or chrome.

10. The multilayered structure of claim 1, further comprising a copper-indium-gallium-diselenide layer adjacent to the contact layer.

11. The multilayered structure of claim 10, wherein the contact layer comprises a chromium or molybdenum.

12. A photovoltaic module comprising:
a glass substrate comprising a cobalt oxide or a copper oxide;
a contact layer adjacent to the glass substrate; and
a copper-indium-gallium-diselenide layer (CIGS) adjacent to the contact layer.

13. The photovoltaic module of claim 12, wherein the glass substrate comprises a cobalt oxide content of about 5 to about 30 wt. %.

14. The photovoltaic module of claim 12, wherein the glass substrate comprises a copper oxide content of about 5 to about 30 wt. %.

15. The photovoltaic module of claim 12, wherein the glass substrate comprises a thermal conductivity of about 1 to about 3 W/K m.

16. The photovoltaic module of claim 12, further comprising a transparent conductive oxide layer adjacent to the CIGS layer.

17. The photovoltaic module of claim 16, further comprising a cadmium sulfide buffer layer between the copper-indium-gallium-diselenide layer and the transparent conductive oxide layer.

18. The photovoltaic module of claim 17, further comprising a zinc-containing layer between the cadmium sulfide buffer layer and the transparent conductive oxide layer.

19. A photovoltaic module comprising:
a glass substrate;
a transparent conductive oxide layer adjacent to the glass substrate;
a cadmium sulfide layer adjacent to the transparent conductive oxide layer;
a cadmium telluride layer adjacent to the cadmium sulfide layer;
a back contact layer adjacent to the cadmium telluride layer; and
a back cover glass comprising a cobalt oxide or a copper oxide adjacent to the back contact layer.

20. A method of manufacturing a photovoltaic module, the method comprising:
depositing a contact layer adjacent to a substrate, wherein the substrate comprises a cobalt oxide or a copper oxide; and
depositing a copper-indium-gallium-diselenide layer adjacent to the contact layer.

21. The method of claim 20, further comprising depositing a cadmium sulfide buffer layer adjacent to the copper-indium-gallium-diselenide layer.

22. The method of claim 21, further comprising depositing a transparent conductive oxide layer adjacent to the cadmium sulfide buffer layer.

23. The method of claim 22, further comprising depositing a zinc-containing layer adjacent to the cadmium sulfide buffer layer and the transparent conductive oxide layer.

24. A method of manufacturing a photovoltaic module, the method comprising:
depositing a transparent conductive oxide layer adjacent to a glass substrate comprising;
depositing a cadmium sulfide layer adjacent to the transparent conductive oxide layer;
depositing a cadmium telluride layer adjacent to the cadmium sulfide layer;
depositing a back contact layer adjacent to the cadmium telluride layer; and
applying a back cover glass comprising a cobalt oxide or a copper oxide adjacent to the back contact layer.

25. A photovoltaic module comprising:
a back glass comprising cobalt oxide or copper oxide;
a contact layer adjacent to the back glass; and
a semiconductor layer adjacent to the contact layer.

26. The photovoltaic module of claim 25, wherein the semiconductor layer comprises a cadmium sulfide layer adjacent to a cadmium telluride layer.

27. The photovoltaic module of claim 25, wherein the semiconductor layer comprises a copper-indium-gallium-diselenide layer (CIGS).

28. The photovoltaic module of claim 25, wherein the semiconductor layer comprises amorphous or crystalline silicon.
